(19) United States
(12) Patent Application Publication
(10) Pub. No.: US 2015/0070855 A1
(43) Pub. Date: Mar. 12, 2015

(54) CIRCUIT BOARD, METHOD FOR MANUFACTURING CIRCUIT BOARD, ELECTRONIC DEVICE, ELECTRONIC APPARATUS, AND MOVING OBJECT

(71) Applicant: Seiko Epson Corporation, Tokyo (JP)

(72) Inventors: Tetsuro MIYAO, Suwa (JP); Tetsuya OTSUKI, Fujimi (JP); Hideki ISHIGAMI, Hachinohe (JP); Yukihiko SHIOHARA, Hachinohe (JP); Hidefumi NAKAMURA, Hachinohe (JP)

(21) Appl. No.: 14/482,290

(22) Filed: Sep. 10, 2014

(30) Foreign Application Priority Data
Sep. 11, 2013 (JP) 2013-188726

(51) Int. Cl. H05K 3/38; H05K 3/46; H05K 1/18; H05K 1/11; H05K 1/09; H05K 1/03

(52) U.S. Cl. CPC H05K 3/388; H05K 1/09; H05K 1/0306; H05K 1/181; H05K 1/115; H05K 3/4644; H05K 3/381
USPC 361/748; 428/433; 174/258; 427/97.6

(57) ABSTRACT

A circuit board includes a ceramics substrate composed of ceramics and a conductor portion provided on the ceramics substrate. The conductor portion is composed of a stacked body including, in order from the ceramics substrate side, an under layer that contains a Group 6 element and a glass material, and a metal layer that contains a low-melting-point metal. A portion of the low-melting-point metal constituting the metal layer migrates to the under layer.

### BACKGROUND

1. Technical Field

The present invention relates to a circuit board, a method for manufacturing a circuit board, an electronic device, an electronic apparatus, and a moving object.

2. Related Art

In the related art, an electronic device configured such that an electronic component such as a vibrating element mounted on a circuit board is accommodated in a package has been known.

The circuit board on which the electronic component is mounted is configured by arranging a wiring (conductor portion) on a ceramics substrate.

Such a circuit board is generally manufactured by applying a conductive composition including copper, tungsten, or the like to a green sheet, and then firing the green sheet (for example, refer to JP-A-7-86741).

However, in the circuit board of the related art, the adhesion between the conductor portion and the ceramics substrate is not sufficiently obtained, giving rise to problems such as peeling of the conductor portion or disconnection of the conductor portion. Moreover, copper flows in manufacture of the circuit board, giving rise to problems such as short circuit of the wiring.

### SUMMARY

An advantage of some aspects of the invention is to provide a circuit board that includes a conductor portion having excellent adhesion with a ceramics substrate and is highly reliable, a method for manufacturing a circuit board by which such a circuit board can be easily manufactured, and an electronic device, an electronic apparatus, and a moving object all of which are highly reliable.

The invention can be implemented as the following forms or application examples.

### Application Example 1

A circuit board according to this application example of the invention includes: a ceramics substrate composed of ceramics; and a conductor portion provided on the ceramics substrate, wherein the conductor portion is composed of a stacked body including, in order from the ceramics substrate side, an under layer that contains a Group 6 element and a glass material, and a metal layer, and a portion of a metal constituting the metal layer is contained in the under layer.

With this configuration, the adhesion between the ceramics substrate and the conductor portion can be made excellent, so that it is possible to provide the circuit board that is highly reliable.

### Application Example 2

In the circuit board according to the application example of the invention, it is preferable that the metal layer contains at least one metal of tin, copper, silver, bismuth, indium, and zinc.

With this configuration, the electrical resistance of the conductor portion can be made smaller.

### Application Example 3

In the circuit board according to the application example of the invention, it is preferable that when the content of the Group 6 element contained in the under layer is A [mass %], and the content of the glass material is B [mass %], the relationship of 1≦A/B≦9 is satisfied.

With this configuration, the adhesion between the ceramics substrate and the conductor portion can be more increased while retaining the shape of the conductor portion.

### Application Example 4

In the circuit board according to the application example of the invention, it is preferable that the circuit board further includes a via.

With this configuration, it is possible to achieve electrical continuity with a surface of the ceramics substrate on the side opposite to a surface thereof on which the conductor portion is provided.

### Application Example 5

In the circuit board according to the application example of the invention, it is preferable that the via includes the Group 6 element, the glass material, and the metal constituting the metal layer.

With this configuration, the adhesion between the via and the ceramics substrate can be improved, and also the adhesion between the conductor portion and the via can be improved.

### Application Example 6

A method for manufacturing a circuit board according to this application example of the invention is a method for manufacturing a circuit board including a ceramics substrate composed of ceramics, and a conductor portion provided on the ceramics substrate, in which the conductor portion is composed of a stacked body including, in order from the ceramics substrate side, an under layer that contains a Group 6 element and a glass material and a metal layer, and a portion of a metal constituting the metal layer is contained in the under layer, the method including: preparing the ceramics substrate, an under layer forming composition containing the Group 6 element and the glass material, and a metal layer forming composition containing the metal; applying the under layer forming composition to the ceramics substrate to form a first coating layer; firing the ceramics substrate on which the first coating layer is formed; applying the metal layer forming composition to the fired first coating layer to form a second coating layer; and firing the ceramics substrate above which the second coating layer is formed to form the under layer and the metal layer.

With this configuration, it is possible to easily manufacture the circuit board that has excellent adhesion between the ceramics substrate and the conductor portion and is highly reliable.

### Application Example 7

In the method for manufacturing the circuit board according to the application example of the invention, it is preferable that firing in the firing of the second coating layer is performed at a temperature higher than a melting point of the metal by 10° C. to 200° C.

With this configuration, a low-melting-point metal can more reliably migrate to (penetrate into) the under layer. As a result, the airtightness of the conductor portion can be more increased.

### Application Example 8

An electronic device according to this application example of the invention includes: the circuit board according to the application example of the invention; an electronic component; and a holding member holding the electronic component on the circuit board.

With this configuration, the electronic device has excellent reliability.

### Application Example 9

An electronic apparatus according to this application example of the invention includes the circuit board according to the application example of the invention.

With this configuration, the electronic apparatus has excellent reliability.

### Application Example 10

A moving object according to this application example of the invention includes the circuit board according to the application example of the invention.

With this configuration, the moving object has excellent reliability.

### BRIEF DESCRIPTION OF THE DRAWINGS

The invention will be described with reference to the accompanying drawings, wherein like numbers reference like elements.

FIG. 1 is a plan view of an electronic device.

FIG. 2 is a cross-sectional view taken along the line A-A in FIG. 1.

FIGS. 3A and 3B are plan views of a vibrating element included in the electronic device shown in FIG. 1.

FIG. 4 is a partial cross-sectional view of a circuit board included in the electronic device shown in FIG. 1.

FIGS. 5A to 5D are diagrams for explaining one example of a method for manufacturing a circuit board according to the invention.

FIG. 6 is a perspective view showing the configuration of a mobile (or notebook) personal computer to which an electronic apparatus according to the invention is applied.

FIG. 7 is a perspective view showing the configuration of a mobile phone (including a PHS) to which an electronic apparatus according to the invention is applied.

FIG. 8 is a perspective view showing the configuration of a digital still camera to which an electronic apparatus according to the invention is applied.

FIG. 9 is a perspective view showing the configuration of an automobile to which a moving object according to the invention is applied.

### DESCRIPTION OF EXEMPLARY EMBODIMENTS

Hereinafter, a circuit board, a method for manufacturing a circuit board, and an electronic device according to the invention will be described in detail based on preferred embodiments shown in the accompanying drawings.

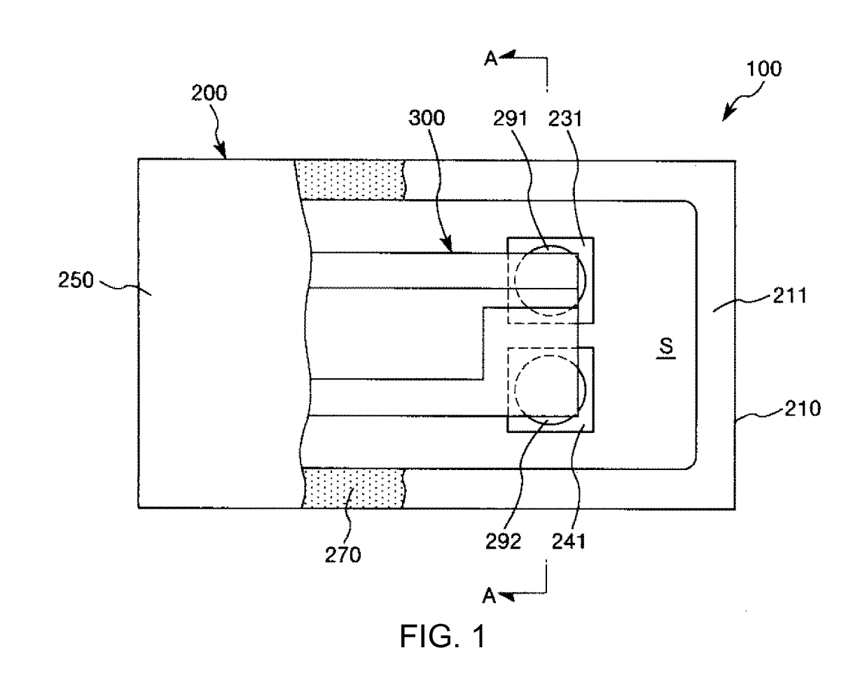

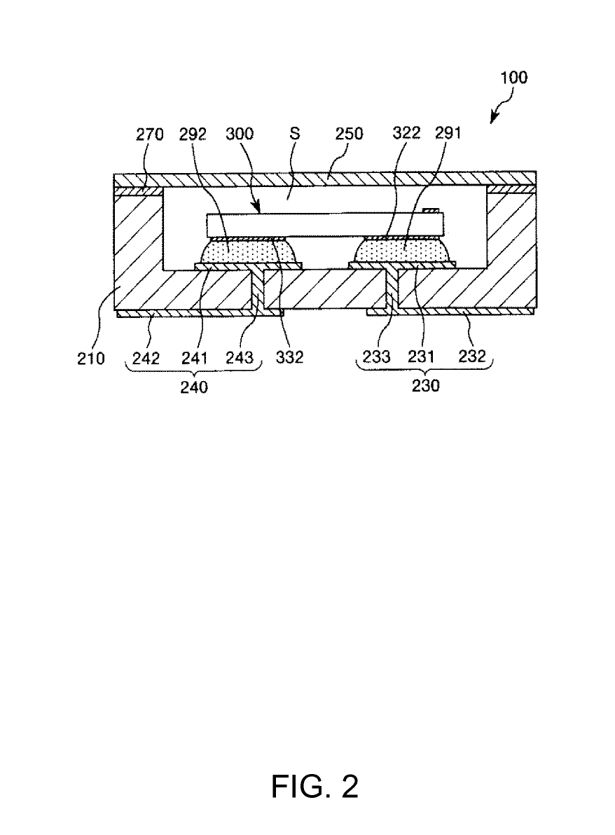

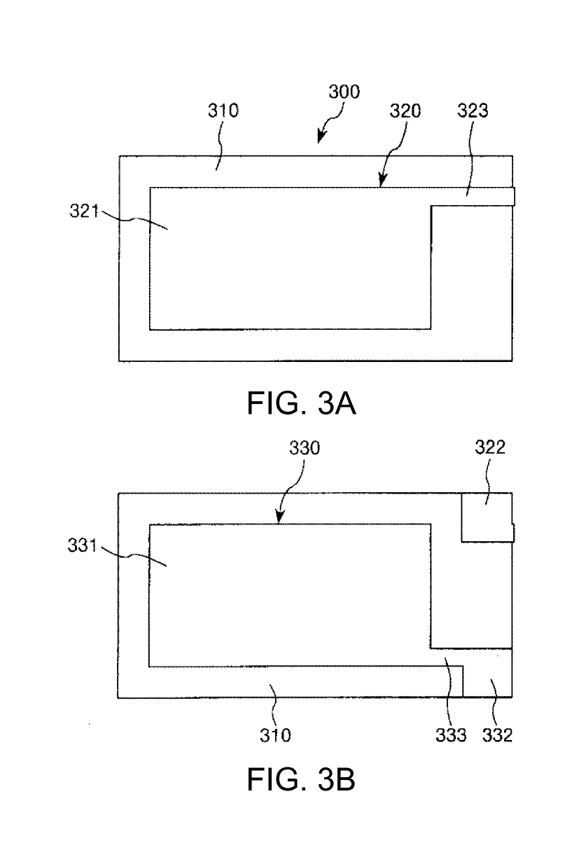

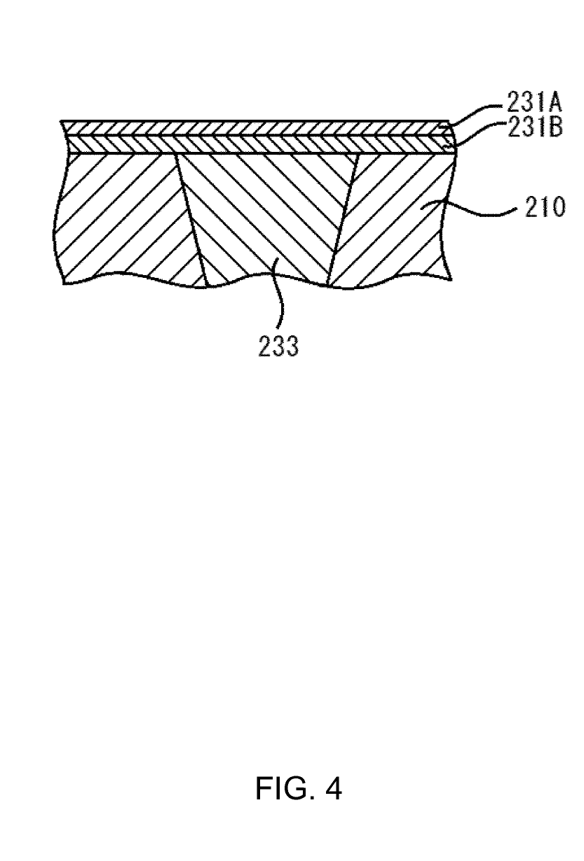

FIG. 1 is a plan view of an electronic device; FIG. 2 is a cross-sectional view taken along the line A-A in FIG. 1; FIGS. 3A and 3B are plan views of a vibrating element included in the electronic device shown in FIG. 1; and FIG. 4 is a partial cross-sectional view of a circuit board included in the electronic device shown in FIG. 1. In the following, the paper near side in FIG. 1 and the upper side in FIG. 2 are referred to as “top”, while the paper far side in FIG. 1 and the lower side in FIG. 2 are referred to as “down”, for convenience of description.

### 1. Electronic Device

First, an electronic device (electronic device including a circuit board according to the invention) according to the invention will be described.

As shown in FIGS. 1 and 2, an electronic device 100 includes a package 200 and a vibrating element (electronic component) 300 accommodated in the package 200.

### Vibrating Element

FIG. 3A is a plan view of the vibrating element 300 as viewed from above; and FIG. 3B is a see-through view (plan view) of the vibrating element 300 as viewed from above.

As shown in FIGS. 3A and 3B, the vibrating element 300 includes a piezoelectric substrate 310 having a rectangular plate-like plan-view shape and a pair of excitation electrodes 320 and 330 formed on surfaces of the piezoelectric substrate 310.

The piezoelectric substrate 310 is a quartz crystal blank that mainly performs thickness-shear vibration. In this embodiment, a quartz crystal blank that is cut at a cut angle called AT-cut is used as the piezoelectric substrate 310. The AT-cut means to cut a quartz crystal blank so as to have a main surface (main surface including an X-axis and a Z′-axis) obtained by rotating a plane (Y-plane) including the X-axis and a Z-axis as the crystal axes of quartz crystal about the X-axis in the counterclockwise direction by an angle of about 35 degrees and 15 minutes from the Z-axis. The longitudinal direction of the piezoelectric substrate 310 coincides with the X-axis as the crystal axis of quartz crystal.

The excitation electrode 320 includes an electrode portion 321 formed on an upper surface of the piezoelectric substrate 310, a bonding pad 322 formed on a lower surface of the piezoelectric substrate 310, and a wiring 323 electrically connecting the electrode portion 321 with the bonding pad 322. On the other hand, the excitation electrode 330 includes an electrode portion 331 formed on the lower surface of the piezoelectric substrate 310, a bonding pad 332 formed on the lower surface of the piezoelectric substrate 310, and a wiring 333 electrically connecting the electrode portion 331 with the bonding pad 332. The electrode portions 321 and 331 are provided to face each other via the piezoelectric substrate 310. The bonding pads 322 and 332 are provided spaced apart from each other at end portions, on the right side in FIGS. 3A and 3B, on the lower surface of the piezoelectric substrate 310.

The excitation electrodes 320 and 330 can be formed by, for example, depositing an under layer of Ni or Cr on the piezoelectric substrate 310 by vapor deposition or sputtering, depositing an electrode layer of Au on the under layer by vapor deposition or sputtering, and then patterning the layers into a desired shape using a photolithography technique and various kinds of etching techniques. With the formation of the under layer, the adhesive property between the piezoelectric substrate 310 and the electrode layer is improved, so that the vibrating element 300 that is highly reliable is obtained.

The vibrating element 300 is fixed to the package 200 via a pair of conductive adhesives (adhesives) 291 and 292.

### Package

As shown in FIGS. 1 and 2, the package 200 includes a cavity-like base substrate (ceramics substrate) 210 with a recess opened on the upper side, a plate-like lid 250, and a metallization layer 270 provided on an upper surface 211 of the base substrate 210 and bonding the base substrate 210 with the lid 250. Each of the base substrate 210 and the lid 250 has a rectangular plan-view shape. In the package 200, the base substrate 210 and the lid 250 are airtightly sealed. The pressure in the interior (an accommodating space S) of the package 200 is reduced. Specifically, the reduced pressure is preferably 100 Pa or less, and more preferably 10 Pa or less.

As the constituent material of the base substrate 210, various kinds of ceramics such as oxide-based ceramics, nitride-based ceramics, and carbide-based ceramics, for example, can be used. On the other hand, as the constituent material of the lid 250, although not particularly limited, various kinds of metal materials such as aluminum, nickel, copper, silver, and gold, and an alloy (for example, Kovar) containing at least one kind of these metal materials, for example, can be used. For example, when ceramics are used as the constituent material of the base substrate 210, it is preferred to use an alloy, such as Kovar, which is a material whose linear expansion coefficient approaches that of the ceramics. Moreover, although the configuration of the metallization layer 270 is not particularly limited, the metallization layer 270 can be configured by, for example, forming a covering layer of Au on an under layer of Ni, Cr, or the like.

The base substrate 210 is provided with a pair of electrodes 230 and 240.

The circuit board is composed of the base substrate 210 and the pair of electrodes 230 and 240.

The electrode 230 includes a connection electrode (conductor portion) 231 provided on an upper surface of the base substrate 210, an external mounting electrode (conductor portion) 232 provided on a lower surface of the base substrate 210, and a through-electrode (via) 233 provided to penetrate through the base substrate 210 and connecting the connection electrode 231 with the external mounting electrode 232. Similarly, the electrode 240 includes a connection electrode (conductor portion) 241 provided on the upper surface of the base substrate 210, an external mounting electrode (conductor portion) 242 provided on the lower surface of the base substrate 210, and a through-electrode (via) 243 provided to penetrate through the base substrate 210 and connecting the connection electrode 241 with the external mounting electrode 242.

As shown in FIG. 4, the connection electrode (conductor portion) 231 is composed of a stacked body including, in order from the base substrate 210 side, an under layer 231B and a metal layer 231A. The external mounting electrode 232, the connection electrode 241, and the external mounting electrode 242 have the same configuration as that of the connection electrode 231, and therefore, the connection electrode 231 will be described as representative.

The metal layer 231A is composed of a material containing a low-melting-point metal.

Examples of the low-melting-point metal include, for example, Sn (tin), Cu (copper), Ag (silver), Bi (bismuth), In (indium), Zn (zinc), and an alloy containing these metals. Among them, at least one kind selected from a group consisting of copper and silver is preferred. Due to this, the electrical resistance of the connection electrode 231 can be made smaller.

The average thickness of the metal layer 231A is preferably from 0.5 μm to 500 μm, and more preferably from 0.5 μm to 50 μm.

The under layer 231B is composed of a material containing a Group 6 element and a glass material. Further, the low-melting-point metal described above migrates to the under layer 231B from the metal layer 231A side. That is, the under layer 231B contains the Group 6 element, the glass material, and the low-melting-point metal.

Among Group 6 elements, particularly at least one kind selected from a group consisting of tungsten (W) and molybdenum (M) is preferably used. Due to this, the shapes of the electrodes can be retained more easily.

Examples of the glass material include a soda glass, a crystalline glass, a silica glass, a lead glass, a potassium glass, a borosilicate glass, and an alkali-free glass.

When the content of the Group 6 element contained in the under layer 231B is A [mass %], and the content of the glass material is B [mass %], the relationship of 1≦A/B≦9 is preferably satisfied, and the relationship of 2≦A/B≦4 is more preferably satisfied. By satisfying the relationships, the adhesion between the base substrate 210 and the connection electrode 231 can be more increased while retaining the shape of the connection electrode 231.

The average thickness of the under layer 231B is preferably from 0.5 μm to 500 μm, and more preferably from 5 μm to 50 μm.

The through-electrode (via) 233 has a function of connecting the connection electrode 231 with the external mounting electrode 232. The through-electrode 243 has the same configuration as that of the through-electrode 233, and therefore, the description thereof is omitted.

A material constituting the through-electrode 233 is not particularly limited as long as the material can provide electrical continuity between the connection electrode 231 and the external mounting electrode 232. However, a material containing a Group 6 element, a glass material, and a low-melting-point metal is preferably used. Due to this, the adhesion between the through-electrode 233 and the base substrate 210 can be improved, and also the adhesion between the through-electrode 233 and the connection electrode 231 or the external mounting electrode 232 can be improved.

In the circuit board described above, the adhesion between the base substrate 210 and the connection electrode 231 is excellent. As a result, the circuit board has excellent reliability.

The vibrating element 300 accommodated in the accommodating space S is supported in a cantilever fashion to the base substrate 210 via the pair of conductive adhesives (holding members) 291 and 292. The conductive adhesive 291 is provided in contact with the connection electrode 231 and the bonding pad 322. Due to this, the connection electrode 231 and the bonding pad 322 are electrically connected via the conductive adhesive 291. The other conductive adhesive 292 is provided in contact with the connection electrode 241 and the bonding pad 332. Due to this, the connection electrode 241 and the bonding pad 332 are electrically connected via the conductive adhesive 292.

The conductive adhesives 291 and 292 are not particularly limited, and, for example, an adhesive obtained by mixing a conductive filler such as a metal powder with a silicone-based, epoxy-based, acrylic-based, polyimide-based, bismaleimide-based, polyester-based, or polyurethane-based resin can be used.

### 2. Method for Manufacturing Circuit Board

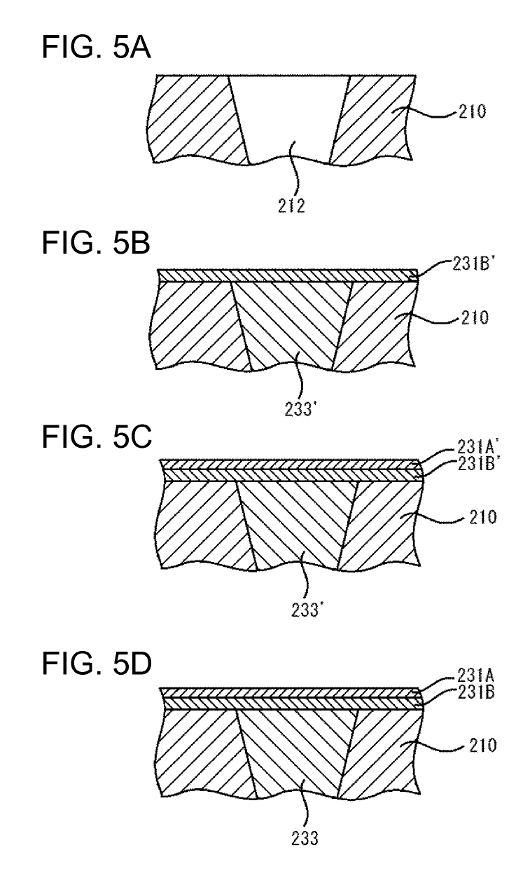

Next, a method for manufacturing a circuit board according to the invention will be described in detail based on FIGS. 5A to 5D.

FIGS. 5A to 5D are diagrams for explaining one example of the method for manufacturing the circuit board according to the invention. In FIGS. 5A to 5D, the upper side is defined as top, while the lower side is defined as down.

First, the base substrate 210 in which a via hole 212 is formed is prepared (refer to FIG. 5A).

The base substrate 210 can be obtained by, for example, firing a green sheet in which a hole for the via hole 212 is formed.

At the same time, an under layer forming composition containing a Group 6 element and a glass material, a metal layer forming composition containing a low-melting-point metal, and a via forming composition containing a Group 6 element and a glass material are prepared.

As the under layer forming composition and the via forming composition, a paste obtained by mixing a powder of Group 6 element, glass material, and the like with an organic vehicle is preferably used.

As the metal layer forming composition, a paste obtained by mixing a powder of low-melting-point metal and the like with an organic vehicle is preferably used.

Next, the via hole 212 is filled with the via forming composition, and thereafter, the under layer forming composition is applied to an upper surface of the base substrate 210, so that a first coating layer 231B′ and a via forming composition layer 233′ are formed (refer to FIG. 5B).

Next, the base substrate 210 on which the first coating layer 231B′ is formed is fired.

A firing temperature in this step is preferably from 300° C. to 1400° C., and more preferably from 600° C. to 900° C.

Next, the metal layer forming composition is applied to the fired first coating layer 231B′ to form a second coating layer 231A′ (refer to FIG. 5C). In this case, the low-melting-point metal contained in the second coating layer 231A′ migrates to the first coating layer 231B′ and the via forming composition filling the via hole.

Next, the base substrate 210 above which the second coating layer 231A′ is formed is fired. Due to this, the circuit board is formed (refer to FIG. 5D).

A firing temperature in this step is preferably higher than the melting point of the low-melting-point metal by 10° C. to 200° C. Due to this, the low-melting-point metal can more reliably migrate to (penetrate into) the under layer 231B and the via (through-electrode) 233. As a result, the airtightness of the conductor portion (connection electrode) 231 and the via (through-electrode) 233 can be more increased.

According to the method described above, it is possible to easily manufacture a circuit board that has excellent adhesion between a ceramics substrate (the base substrate 210) and a conductor portion (the connection electrode 231) and is highly reliable.

### 3. Electronic Apparatus

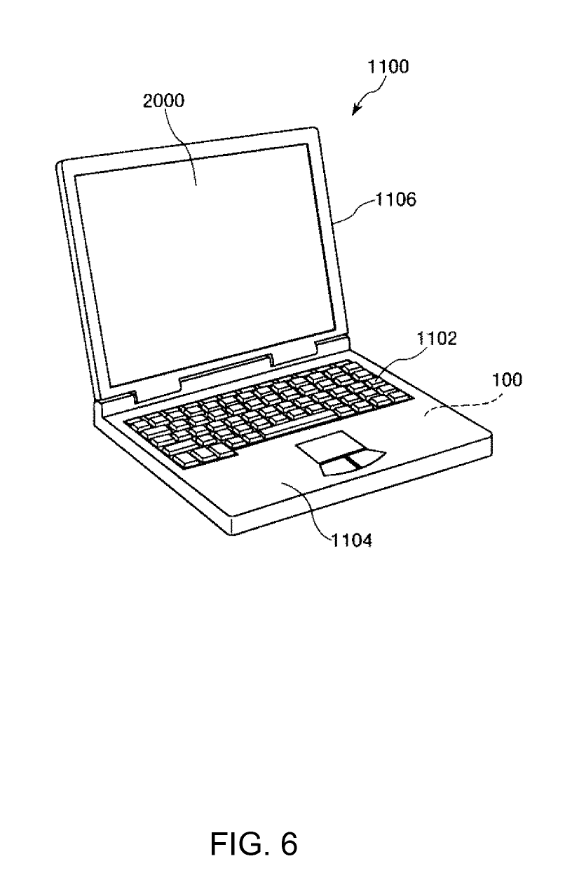

Next, an electronic apparatus (electronic apparatus according to the invention) including an electronic device according to the invention will be described in detail based on FIGS. 6 to 8.

FIG. 6 is a perspective view showing the configuration of a mobile (or notebook) personal computer to which an electronic apparatus according to the invention is applied. In the drawing, the personal computer 1100 is composed of a main body portion 1104 including a keyboard 1102 and a display unit 1106 including a display portion 2000. The display unit 1106 is rotationally movably supported relative to the main body portion 1104 via a hinge structure portion. In the personal computer 1100, the electronic device 100 that functions as a filter, a resonator, a reference clock, or the like is built.

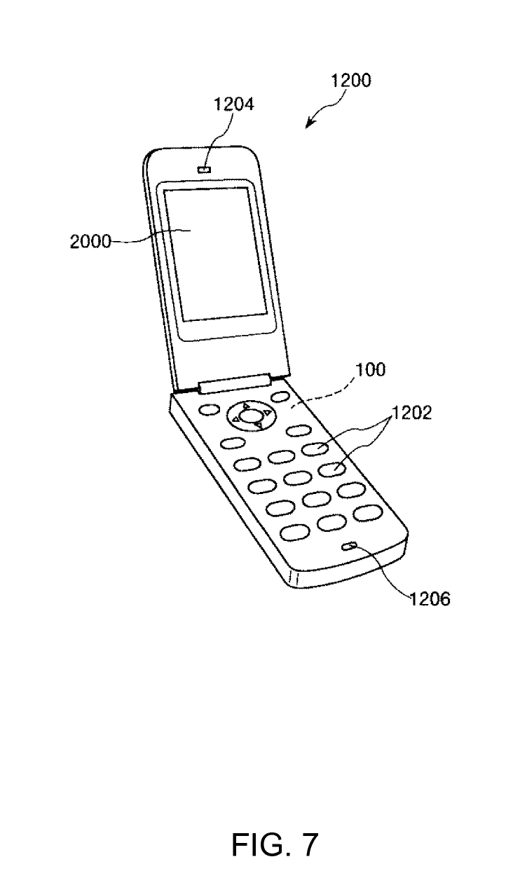

FIG. 7 is a perspective view showing the configuration of a mobile phone (including a PHS) to which an electronic apparatus according to the invention is applied. In the drawing, the mobile phone 1200 includes a plurality of operation buttons 1202, an earpiece 1204, and a mouthpiece 1206. The display portion 2000 is arranged between the operation buttons 1202 and the earpiece 1204. In the mobile phone 1200, the electronic device 100 that functions as a filter, a resonator, or the like is built.

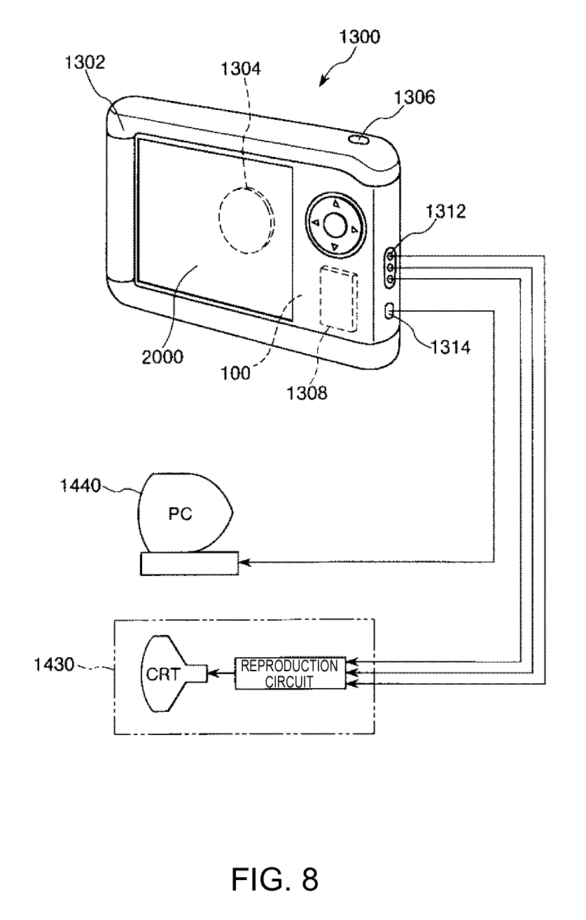

FIG. 8 is a perspective view showing the configuration of a digital still camera to which an electronic apparatus according to the invention is applied. In the drawing, connections with external apparatuses are also shown in a simplified manner. Here, usual cameras expose a silver halide photographic film with an optical image of a subject, whereas the digital still camera 1300 photoelectrically converts an optical image of a subject with an imaging element such as a CCD (Charge Coupled Device) to generate imaging signals (image signals).

A display portion is provided on the back surface of a case (body) 1302 in the digital still camera 1300 and configured to perform display based on the imaging signals generated by the CCD. The display portion functions as a finder that displays a subject as an electronic image. Moreover, on the front side (the rear side in the drawing) of the case 1302, alight receiving unit 1304 including an optical lens (imaging optical system) and the CCD is provided.

When a photographer confirms a subject image displayed on the display portion and presses down a shutter button 1306, imaging signals of the CCD at the time are transferred to and stored in a memory 1308. Moreover, in the digital still camera 1300, a video signal output terminal 1312 and a data communication input/output terminal 1314 are provided on the side surface of the case 1302. Then, as shown in the drawing, a TV monitor 1430 and a personal computer 1440 are connected as necessary to the video signal output terminal 1312 and the data communication input/output terminal 1314, respectively. Further, the imaging signals stored in the memory 1308 are output to the TV monitor 1430 or the personal computer 1440 by a predetermined operation. In the digital still camera 1300, the electronic device 100 that functions as a filter, a resonator, or the like is built.

In addition to the personal computer (mobile personal computer) in FIG. 6, the mobile phone in FIG. 7, and the digital still camera in FIG. 8, an electronic apparatus including the electronic device according to the invention can be applied to, for example, inkjet ejection apparatuses (for example, inkjet printers), laptop personal computers, television sets, video camcorders, video tape recorders, car navigation systems, pagers, electronic notebooks (including those with communication function), electronic dictionaries, calculators, electronic gaming machines, word processors, workstations, videophones, surveillance TV monitors, electronic binoculars, POS terminals, medical equipment (for example, electronic thermometers, sphygmomanometers, blood glucose meters, electrocardiogram measuring systems, ultrasonic diagnosis apparatuses, electronic endoscopes), fishfinders, various kinds of measuring instrument, indicators (for example, indicators used in vehicles, aircraft, and ships), flight simulators, and the like.

### 4. Moving Object

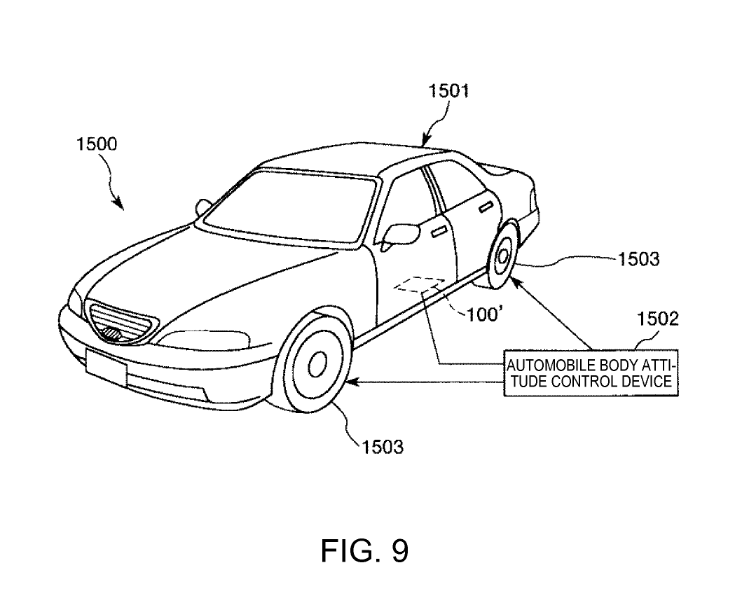

Next, a moving object (moving object according to the invention) including an electronic device according to the invention will be described in detail based on FIG. 9.

FIG. 9 is a perspective view showing the configuration of an automobile to which a moving object according to the invention is applied. The electronic device according to the invention is incorporated as, for example, a gyro sensor into the automobile 1500. In this case, an electronic device 100′ using as a functional element an angular velocity detecting element (gyro element) instead of the vibrating element 300 can be used. According to the electronic device 100′, the attitude of an automobile body 1501 can be detected. Detection signals of the electronic device 100′ are supplied to an automobile body attitude control device 1502. The automobile body attitude control device 1502 can detect, based on the signals, the attitude of the automobile body 1501 to control the hardness and softness of a suspension according to the result of detection or control the braking force of individual wheels 1503. In addition, the attitude control can be utilized for bipedal walking robots or radio-controlled helicopters. As described above, the electronic device 100′ is incorporated for realizing the attitude control of various kinds of moving objects.

The circuit board, the method for manufacturing the circuit board, the electronic device, the electronic apparatus, and the moving object according to the invention have been described so far based on the embodiments shown in the drawings. However, the invention is not limited to the embodiments. The configuration of each portion can be replaced with any configuration having the same function. Moreover, any other configurations may be added to the invention. Moreover, the embodiments may be appropriately combined with each other.

In the embodiment described above, a configuration has been described in which the base substrate is of a cavity type and the lid is plate-like. However, the shapes of the base substrate and the lid are not particularly limited as long as when the base substrate and the lid are bonded together to form a package, a space for accommodating a vibrating element can be formed in the interior of the package. For example, contrary to the embodiment described above, the base substrate may be plate-like, and the lid may be of a cavity type. Moreover, both the base substrate and the lid may be of a cavity type.

In the embodiment described above, a configuration has been described in which an AT-cut vibrator is used as an electronic component. However, the electronic component is not limited to the AT-cut vibrator. For example, the electronic component may be a tuning fork type vibrator or a gyro element.

### Example

### 1 Manufacture of Circuit Board

### 1. Production of Under Layer Forming Composition and Via Forming Composition

A tungsten powder (a particle diameter of about 3 μm) and a glass powder (a particle diameter of about 2 μm) were prepared at a ratio by weight of 80:20, followed by being mixed with an organic vehicle to produce an under layer forming composition and a via forming composition.

### 2. Production of Metal Layer Forming Composition 2-1.

First, a silver powder (a particle diameter of about 3 μm), a copper powder (a particle diameter of about 3 μm), and a zinc powder (a particle diameter of 7 μm) were prepared at a ratio by weight of 50:20:30, followed by being mixed with an organic vehicle to produce a metal layer forming composition 1.

Moreover, a copper powder (a particle diameter of about 3 μm) and a phosphorus powder (a particle diameter of about 5 μm) were prepared at a ratio by weight of 93:7, followed by being mixed with an organic vehicle to form a metal layer forming composition 2.

### 3. Production of Ceramics Substrate

A green sheet with a hole (via hole) of 250 μm was heated in a hydrogen atmosphere while raising a temperature at a rate of 200° C./H or less, and fired at 1500° C. for 3 hours to produce a ceramics substrate.

4. Filling of Via Hole with Via Forming Composition

The via forming composition was screen-printed into the via hole of the fired ceramics substrate, so that the via hole was filled with the via forming composition.

### 5. Formation of First Coating Layer

The under layer forming composition was screen-printed onto the ceramics substrate to form a first coating layer.

### 6. Firing

The ceramics substrate on which the first coating layer was formed was heated in a nitrogen atmosphere while raising a temperature at a rate of 200° C./h or less, and fired under the conditions of 900° C. for 0.5 hours.

### 7. Formation of Second Coating Layer

The metal layer forming composition 1 or the metal layer forming composition 2 was applied by screen printing at a conductor portion on the fired first coating layer to form a second coating layer.

### 8. Firing

The ceramics substrate above which the second coating layer was formed was heated in a nitrogen atmosphere while raising a temperature at a rate of 200° C./h or less, and fired under the conditions of 800° C. for 0.5 hours. Due to this, two circuit boards formed respectively using the metal layer forming composition 1 and the metal layer forming composition 2 were obtained.

### 2 Evaluation of Circuit Board

For the evaluation of the circuit boards, the adhesion (crack or peeling) of the via and the conductor portion and the shape retaining property thereof were evaluated using an optical microscope, the filling property of the under layer forming composition and the metal layer forming compositions was evaluated using an electron microscope, the electrical continuity was evaluated using a continuity tester, and the airtightness was evaluated by an alcohol bleed-out test. As a result, all of the evaluation items were favorable.

The above result has revealed that the conductor portion has excellent adhesive property, filling property, wiring shape retaining property, electrical continuity, and airtightness and that the circuit board including the conductor portion is a board having very excellent reliability.

The entire disclosure of Japanese Patent Application No. 2013-188726, filed Sep. 11, 2013 is expressly incorporated by reference herein.

What is claimed is:

1. A circuit board comprising:
a ceramics substrate composed of ceramics; and
a conductor portion provided on the ceramics substrate, wherein
the conductor portion is composed of a stacked body including, in order from the ceramics substrate side, an under layer that contains a Group 6 element and a glass material, and a metal layer, and
a portion of a metal constituting the metal layer is contained in the under layer.

2. The circuit board according to claim 1, wherein
the metal layer contains at least one metal of tin, copper, silver, bismuth, indium, and zinc.

3. The circuit board according to claim 1, wherein
when the content of the Group 6 element contained in the under layer is A [mass %], and the content of the glass material is B [mass %], the relationship of 1≦A/B≦9 is satisfied.

4. The circuit board according to claim 1, further comprising a via.

5. The circuit board according to claim 4, wherein
the via includes the Group 6 element, the glass material, and the metal constituting the metal layer.

6. A method for manufacturing a circuit board, the circuit board including a ceramics substrate composed of ceramics, and a conductor portion provided on the ceramics substrate, in which the conductor portion is composed of a stacked body including, in order from the ceramics substrate side, an under layer that contains a Group 6 element and a glass material and a metal layer, and a portion of a metal constituting the metal layer is contained in the under layer,
the method comprising:
preparing the ceramics substrate, an under layer forming composition containing the Group 6 element and the glass material, and a metal layer forming composition containing the metal;
applying the under layer forming composition to the ceramics substrate to form a first coating layer;
firing the ceramics substrate on which the first coating layer is formed;
applying the metal layer forming composition to the fired first coating layer to form a second coating layer; and
firing the ceramics substrate above which the second coating layer is formed to form the under layer and the metal layer.

7. The method for manufacturing the circuit board according to claim 6, wherein
firing in the firing of the second coating layer is performed at a temperature higher than a melting point of the metal by 10° C. to 200° C.

8. An electronic device comprising:
the circuit board according to claim 1;
an electronic component; and
a holding member holding the electronic component on the circuit board.

9. An electronic apparatus comprising the circuit board according to claim 1.

10. A moving object comprising the circuit board according to claim 1.
